(19) United States
(12) Patent Application Publication
(10) Pub. No.: US 2007/0052050 A1
(43) Pub. Date: Mar. 8, 2007

(54) Backside thinned image sensor with integrated lens stack

(76) Inventor: Bart Dierickx, Edegem (BE)

Correspondence Address: Daniel E. Ovanezian;BLAKELY, SOKOLOFF, TAYLOR & ZAFMAN LLP, Seventh Floor, 12400 Wilshire Boulevard, Los Angeles, CA, 90025, US

(21) Appl. No.: 11/221,613

(22) Filed: Sep. 7, 2005

(51) Int. Cl. H01L 31/0232

(52) U.S. Cl. 257/432; 257/E21.127

(57) ABSTRACT

A method and apparatus for a backside thinned image sensor with an integrated lens stack.

### TECHNICAL FIELD

Embodiments of the present invention relate to image sensors and, more particularly, to backside thinned image sensors with integrated lens stacks.

### BACKGROUND

Solid-state image sensors have found widespread applications, most notably in digital camera systems. Generally, solid-state image sensors are composed of a matrix of photosensitive elements in series with switching and amplifying elements. The photosensitive elements may be, for example, photoreceptors, photo-diodes, phototransistors, charge-coupled devices (CCD), or the like. Each photosensitive element receives an image of a portion of a scene being imaged. A photosensitive element along with its accompanying electronics is called a picture element or pixel. The image obtaining photosensitive elements produce an electrical signal indicative of the light intensity of the image. The electrical signal of a photosensitive element is typically a current, which is proportional to the amount of electromagnetic radiation (light) falling onto that photosensitive element.

Some image sensors are fabricated using metal oxide semiconductor (MOS) technology, such as the image sensor illustrated in FIG. 1. Of these image sensors, image sensors with passive pixels and image sensors with active pixels (active pixel sensors, APS) are distinguished. The difference between these two types of pixel structures is that an APS amplifies the charge that is collected on the pixel's photosensitive element. A passive pixel does not perform signal amplification and requires a charge sensitive amplifier that is not integrated in the pixel.

One standard used to measure the performance of a MOS-technology image sensors is the product of the “quantum efficiency” (QE) and the “fill factor” (FF); this product is known as the “QE*FF.” In this expression, fill factor is defined as the ratio of the light-sensitive area of a pixel with respect to the pixel's total area, while quantum efficiency is defined as the ratio of the number of photo-electrons effectively generated in a pixel per impinging photon. As the quantum efficiency and fill factor improve, the QE*FF of the image sensor approaches a value of 1.

Unfortunately, the QE*FF of an APS is limited by the individual limitations on the quantum efficiency or the fill factor. The quantum efficiency of an APS 14 (see FIG. 1) can be limited by several effects: when photons 10 are lost for conversion due to the reflection off of the dielectrics 12, when photons 10 are not absorbed in the acquisition layer, when the generated electrons recombine before reaching the collection region, or when the electrons are not collected because the electrons are absorbed by other features of the image sensor. The fill factor of APS 14 can also be limited by several effects: the obscuration by the metallization 16 or silicides associated with the circuit elements of the pixel, the collection of photons 10 by the insensitive junctions of the pixel, or the recombination of photo-generated carriers with the majority carriers.

Several solutions have been proposed to improve the QE*FF by improving the fill factor and/or the quantum efficiency of MOS-technology APS. For example, manufacturers have proposed backside thinning the image sensor and illumination from the backside, so as to remove some of the most important factors that compromise the FF and QE.

For a completely different reason (combining the lens and imagers in to a camera at wafer level), designers have proposed bonding an integrated lens stack (ILS) 200 to a CMOS image sensor (CIS) 202 in a shellcase (produced by Shellcase Inc of Israel) package or other wafer-scale package (WSP) 204, such as those produced by Schott Electronics GMBH of Germany.

Another solution proposed by some MOS-technology APS designers is the thinning of the backside of the substrate of APS 14, as illustrated in FIG. 3. Backside thinning (BST) the substrate of APS 14 facilitates the detection of photons 10 through the backside of APS 14. BST APS 14 greatly increases both the fill factor and the quantum efficiency of the device; sometimes leading to a 3× improvement in QE*FF.

Although BST is a performance enhancement, fabricating a BST wafer of APS is a challenge. BST is a complex processing step, leading to increased production costs and lowered yields. In addition, BST reduces the depth of the substrate of the wafer to less than 5-10 micrometers. A typical wafer is mechanically supported by a substrate layer that is hundreds of micrometers thick. Consequently, the wafer is very fragile, so handling the wafer during fabrication and packaging the individual APS is problematic.

One publication describes creating an image sensor composed of a backside thinned wafer combined with a type of integrated lens stack (see WALORI EU project no.: IST-2001-35366). Despite the conceptual application of the combined technology, there are considerable manufacturing hurdles hampering the commercial development of this combined technology.

### BRIEF DESCRIPTION OF THE DRAWINGS

The present invention is illustrated by way of example, and not by way of limitation, in the figures of the accompanying drawings in which:

FIG. 1 illustrates an image sensor.

FIG. 2 illustrates an integrated lens stack.

FIG. 3 illustrates a backside illuminated image sensor.

FIG. 4A-4I illustrates embodiments of a manufacturing process for a backside thinned image sensor with an integrated lens stack.

FIG. 5 presents a flowchart of an embodiment of the fabrication for a backside thinned image sensor with an integrated lens stack.

FIG. 6 illustrates an expanded view of one embodiment of backside thinned image sensor with an integrated lens stack.

FIG. 7 illustrates one embodiment of an image sensor wafer, optical handle wafer and integrated lens stack wafer.

FIG. 8 illustrates one embodiment of backside thinned image sensor with an integrated lens stack.

FIG. 9 illustrates one embodiment of a camera system having backside thinned image sensor with an integrated lens stack.

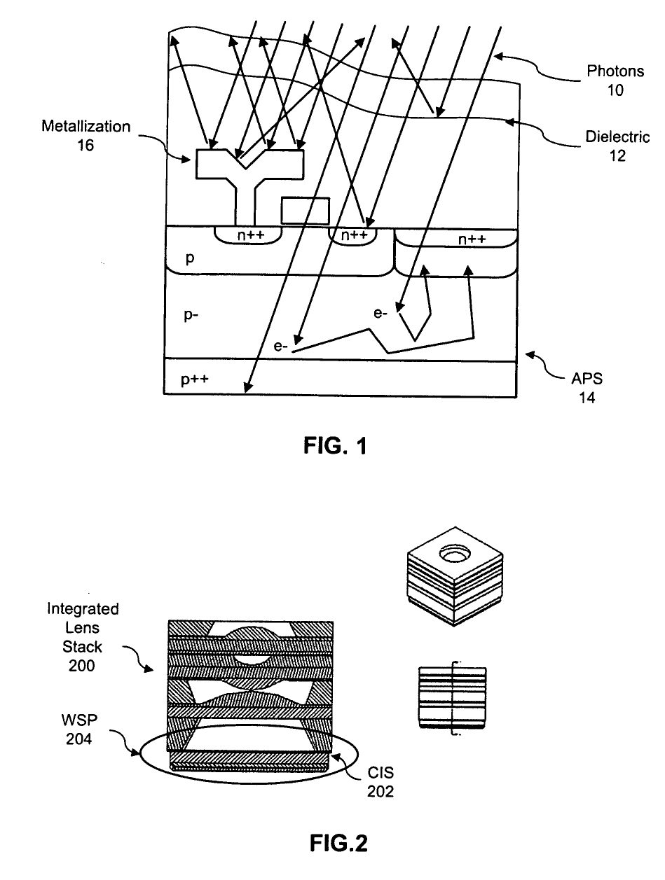

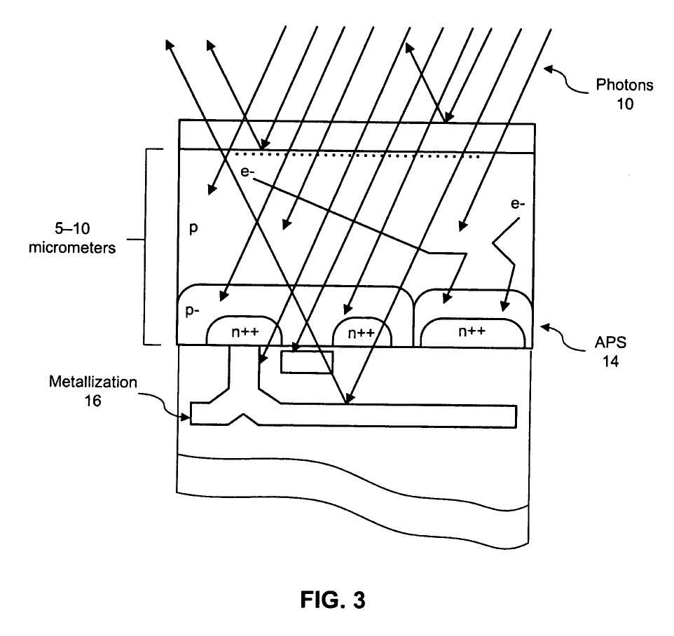

### DETAILED DESCRIPTION

In the following description, numerous specific details are set forth, such as examples of specific commands, named components, connections, integrated lens stacks, MOS-technology fabrication steps, etc., in order to provide a thorough understanding of embodiments of the present invention. It will be apparent, however, to one skilled in the art that embodiments of present invention may be practiced without these specific details. In other instances, well known components or methods have not been described in detail but rather in a block diagram in order to avoid unnecessarily obscuring the present invention. Thus, the specific details set forth are merely exemplary. The specific details may be varied from and still be contemplated to be within the spirit and scope of the present invention. The term “coupled to” as used herein may mean coupled directly to or indirectly to through one or more intervening components.

A method and apparatus for backside thinned image sensors with integrated lens stacks is described. Although discussed at times in relation to a CMOS image sensor with an attached integrated lens stack, the methods and apparatus discussed herein can also be used to form backside thinned image sensor from other technologies using assorted lens arrangements coupled together in various configurations.

Image sensing circuits on the front side of a CMOS image sensor (CIS) convert incident light into a digital signal. For one embodiment, it is possible to improve the performance of such a CIS by thinning the backside of the substrate of the CIS, allowing the CIS to detect light that is illuminating the backside of the substrate. With substrate thin enough to allow detection of light through the backside of the CIS, the substrate is no longer thick enough to provide sufficient mechanical support to the CIS. The CIS is therefore very susceptible to damage from handling and packaging. In order to prevent such damage, a transparent handling layer can be bonded to the backside of the thinned CIS. The transparent handling layer provides both a means for handling and mechanical support for the CIS, while still allowing the backside illumination of the CIS. It one embodiment, the backside thinned device may be used with a transparent handle wafer, without integration of a lens stack.

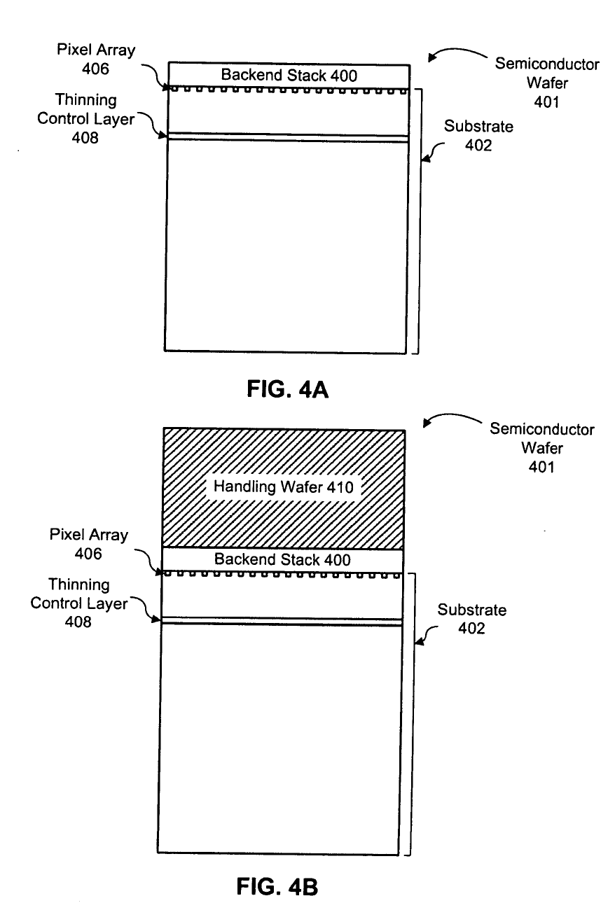

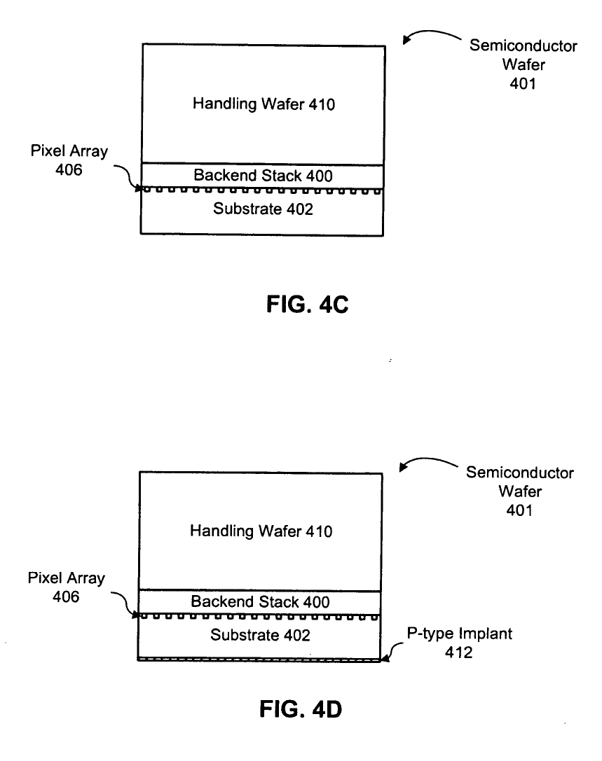

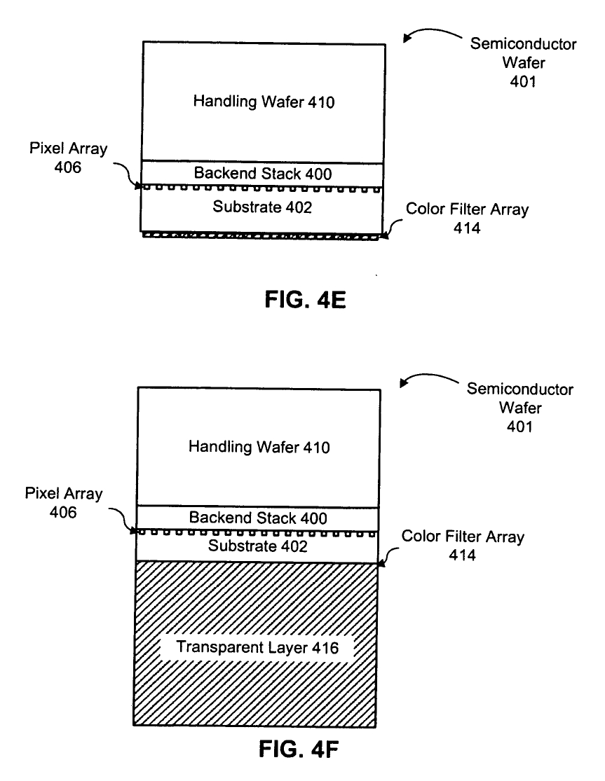

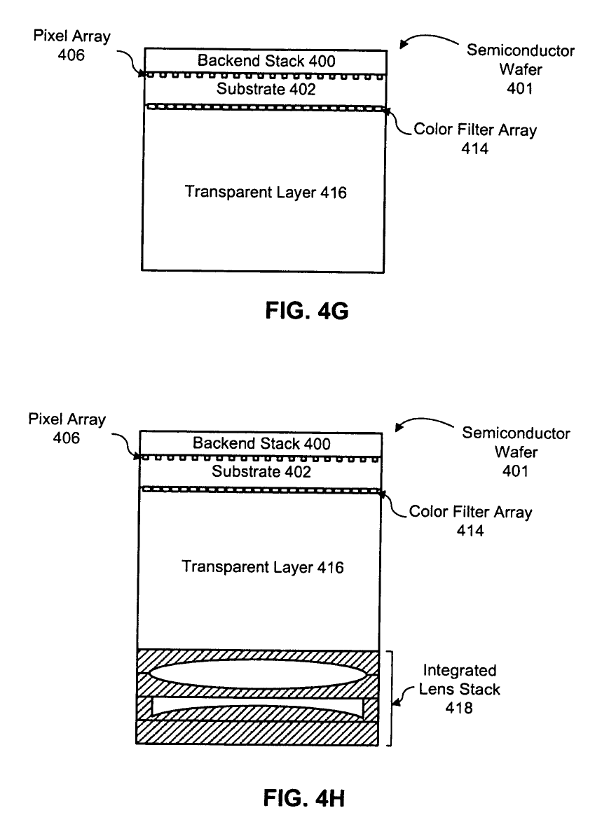

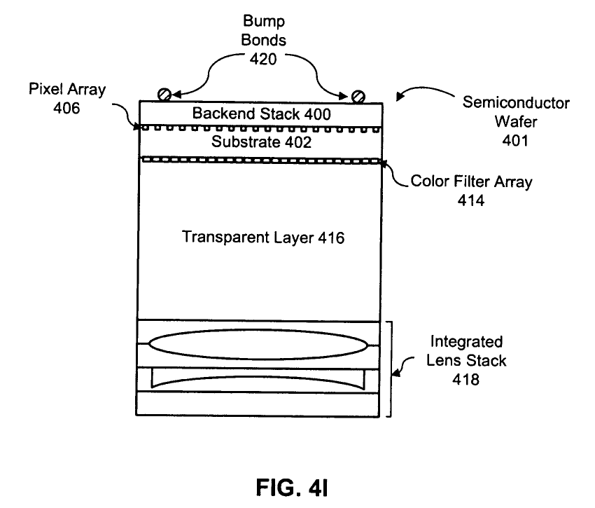

FIG. 4A-4I illustrates embodiments of a manufacturing process for a backside thinned image sensor with an integrated lens stack. The manufacturing process starts with substrate 402. In one embodiment, substrate 402 is a silicon-on-insulator wafer (SOI). Alternatively, substrate 402 can be a special epitaxial wafer, such as a silicon-on-sapphire (SOS), some other type of epitaxial wafer, or a wafer that has a thinning control layer embodied at some depth. Manufacturing techniques for such wafers are know to one of ordinary skill in the art and, accordingly, are not described in detail herein. During the first steps of the manufacturing process, circuit features are fabricated on substrate 402. Following these manufacturing steps, as illustrated in FIG. 4A, semiconductor wafer 401 includes pixel array 406, backend stack 400, and substrate 402. Pixel array 406 includes an array of metal oxide semiconductor technology (MOS-technology) image sensing circuits (“pixels”) located under backend stack 400. MOS-technology image sensors are known in the art; accordingly, a more detailed description is not provided. Backend stack 400 includes the signal routing layers for semiconductor wafer 401.

In one embodiment, semiconductor wafer 401 includes thinning control layer 408 implanted in substrate 402. Thinning control layer 408 provides a chemical stop for the etching process used to remove part of substrate 402 in a later manufacturing step. In one embodiment, thinning control layer 408 is a Separation by IMplantation of OXygen (SIMOX) layer. One method of creating a SIMOX layer is to use an oxygen ion beam implantation process followed by high temperature annealing to create a buried SiO₂ layer. Based on the etch selectivity of Si to SiO₂ in alkaline aqueous solutions, for example, this SiO₂ layer is employed as an etch-stop in preparation of Silicon-on-insulator (SOI) materials. In an alternative embodiment, thinning control layer 408 may be another type of etch stop, such as a carbon-implanted etch-stop. Alternatively, other etch stopping techniques may be based on selective etch speed differences between materials or between different dopant types or dopant concentration levels, or by electro-chemical etch stopping on a junction, or by partial mechanical grinding, polishing or CMP-ing. Such etch stopping techniques are known to one of ordinary skill in the art; accordingly, a detailed discussion is not provided.

In one embodiment, during the next step in the manufacturing process, as illustrated in FIG. 4B, handle wafer 410 is bonded (in a de-bondable manner) to the semiconductor wafer 401. Handle wafer 410 is used to handle semiconductor wafer 401 and to provide mechanical support for semiconductor wafer 401 during subsequent manufacturing steps. Note that handle wafer 410 obscures backend stack 400, so that direct electrical connections cannot be made to backend stack 400.

During the next step in the manufacturing process, as illustrated in FIG. 4C, material is removed from substrate 402 of semiconductor wafer 401. In one embodiment, the material is removed from substrate 402 by grinding, lapping, or etching. For example, grinding can be used to remove most of the material from substrate 402, while the remainder of the material is removed by etching down to thinning control layer 408. Thinning control layer 408 is then also exposed and etched. Alternatively, etching or grinding can be used to remove all the material from substrate 402. In another embodiment, techniques such as wafer cleaving the water-jet-into-porous-Si are used to remove the material from substrate 402.

Following the removal of the material from substrate 402, substrate 402 is thin enough to facilitate the detection of light by pixels in pixel array 406 through the backside surface of semiconductor wafer 401. Unlike the front side surface, the backside surface has no circuit features to reflect or absorb incident light, so the amount of light that reaches pixel array 406 significantly increases. In addition, the electrons freed by the incident light travel a shorter distance within substrate 402 before encroaching on the collection region of a pixel. Hence, the electrons scattered under a given pixel are more likely to be collected by that pixel. This reduces the amount of optical cross-talk between the pixels in pixel array 406. In one embodiment, in order to facilitate the detection of visible light, substrate 402 is fabricated to be approximately 5-10 micrometers thick. Alternatively, thinner or thicker substrates may be used to detect selected wavelengths of electromagnetic waves. For example, a slightly thicker substrate can be used to detect infrared light.

Because substrate 402 is so thin, semiconductor wafer 401 could be very vulnerable to damage from handling during subsequent manufacturing steps. However, handling wafer 410 provides the handling means and mechanical support necessary to protect semiconductor wafer 401.

In one embodiment, a shallow p-type implant 412 is disposed in the backside of substrate 402, as illustrated in FIG. 4D. P-type implant 412 prevents electrons from within the substrate from gathering at backside surface of substrate 402. If allowed to gather at the backside surface, these electrons can cause a portion of the incident light to be reflected, diminishing the amount of light incident on pixel array 406. In another embodiment, a color filter array 414 is disposed on the backside of substrate 402, as illustrated in FIG. 4E. Color filter array 414 filters the light by color before the light illuminates the backside of substrate 402. In one embodiment, an anti-reflective layer may be disposed on substrate 402. The anti-reflective layer further reduces the reflection of incident light from the backside surface of the substrate. Alternatively, an anti-reflection layer may be disposed in other regions, for example, between the image sensor and the transparent layer 416 and/or between the transparent layer 416 and the integrated lens stack 418.

During the next step in the manufacturing process, as illustrated in FIG. 4F, transparent layer (e.g., wafer or plate) 416 is bonded to semiconductor wafer 401. Transparent layer 416 provides both a means for handling the wafer and mechanical support during subsequent manufacturing steps.

During the next step in the manufacturing process, as illustrated in FIG. 4G, handling wafer 410 is removed from semiconductor wafer 401. Because transparent layer 416 provides a means for handling and mechanical support for semiconductor wafer 401, handling wafer 410 is no longer needed. Removing handling wafer 410 exposes backend stack 400, facilitating direct electrical connections to the metal routing layers of semiconductor wafer 401. Consequently, external electrical connections can be placed directly on the front side of semiconductor wafer 401, facilitating the wafer-testing of the circuits on semiconductor wafer 401.

During the next step in the manufacturing process, as illustrated in FIG. 4H, integrated lens stack 418 is bonded to transparent layer (e.g., wafer or plate) 416. Integrated lens stack 418 can serve many purposes, such as focusing light, attenuating light, or concentrating one wavelength of light on the backside of semiconductor wafer 401. Integrated lens stack 418 may include layers such as collimating lenses, focusing lenses, spacers, and mirrored layers. In one embodiment, the layers of integrated lens stack 418 are bonded together using a thermosetting resin. Alternatively, the layers of integrated lens stack 418 are coupled together using a UV-setting bonding process or another type of bonding process. Integrated lens stack 418 also provides additional mechanical support. Embodiments of integrated lens stack 418 with five lens layers or two lens layers can be commercially obtained through Anteryon BV, The Netherlands. Alternatively, integrated lens stacks 418 with different numbers of lens layers from other lens manufacturers are used.

In one embodiment, integrated lens stack 418 is bonded to transparent layer 416 with no air gap between them. Alternatively, integrated lens stack 418 can be bonded to transparent layer 416 with a spacer or another type of lens layer that leaves an air gap between integrated lens stack 418 and transparent layer 416.

In the final step of the manufacturing process, as illustrated in FIG. 4I, bump bonds 420 are added to semiconductor wafer 401. Following this step, semiconductor wafer 401 is ready for dicing into individual image sensor modules. In one embodiment, the individual sensor modules are ready-to-use imaging modules. Consequently, the image sensor modules can be placed in image sensing applications without additional lenses or external adjustments.

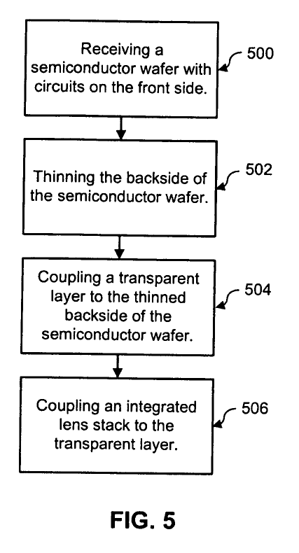

FIG. 5 presents a flowchart of an embodiment of the fabrication for a backside thinned image sensor with an integrated lens stack. A semiconductor wafer with image sensing circuits on the front side is received, step 500. The backside of the semiconductor wafer is thinned, step 502. A transparent layer is added to thinned backside of the semiconductor wafer, step 504. An integrated lens stack is coupled to the transparent layer, step 506.

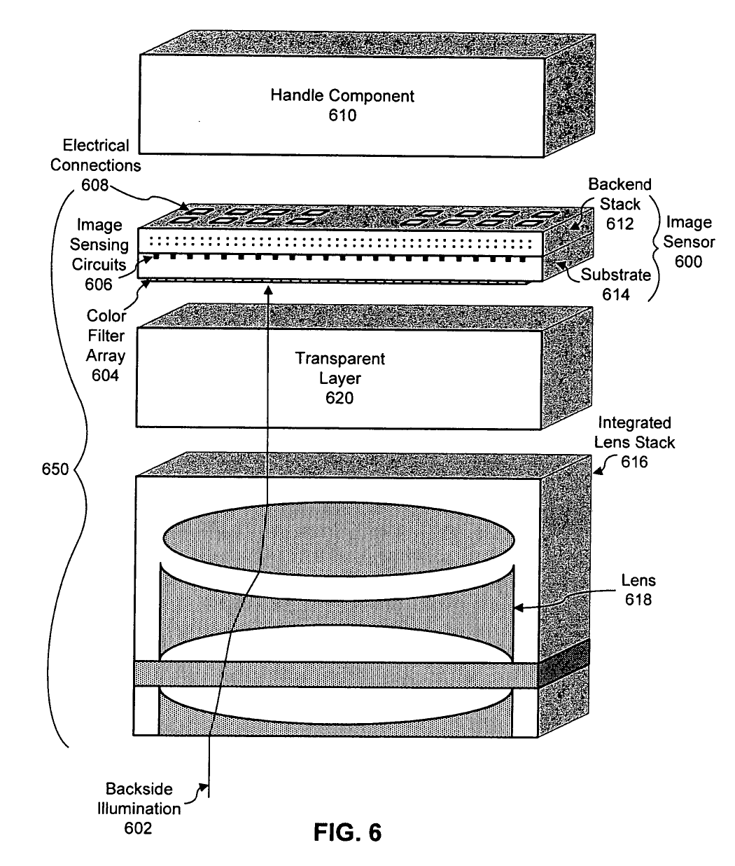

FIG. 6 illustrates an expanded view of one embodiment of backside thinned image sensor with an integrated lens stack device 650. Device 650 may include an image sensor 600, a transparent layer 620 coupled to the image sensor 600, and integrated lens stack 616 coupled to the transparent layer 620. In one embodiment, image sensor 600 includes a backend stack 612 coupled to a substrate 614. Substrate 614 includes an array of image sensing circuits 606. The backside surface of substrate 614 has been thinned so that image sensing circuits 606 can detect light through the backside surface of substrate 614.

In one embodiment, substrate 614 is fabricated to be approximately 5-10 micrometers thick in order to facilitate the detection of visible light. Alternatively, substrate 614 may be fabricated to be thinner or thicker to detect selected wavelengths of electromagnetic waves. For example, a slightly thicker substrate can be used to detect infrared light.

Backend stack 612 includes the metal routing layers for image sensor 600. Electrical connections 608, which are located on the front side of backend stack 612, are the external electrical connections for image sensor 600.

In one embodiment, a color filter array 604 is disposed to the backside surface of substrate 614. Color filter array 604 allows only certain colors of light to hit selected pixels.

A handle component 610 may be used during the manufacture of device 650 to provide mechanical support and a means for handling image sensor 600 during the early stages of the manufacturing process. In an intermediate stage of the manufacturing process, transparent layer 620 is bonded to the thinned backside surface of substrate 614, also providing a handling means and mechanical support for image sensor 600. Following the bonding of transparent layer 620, handle component 610 is no longer necessary and is removed (and discarded) in a subsequent manufacturing step.

Integrated lens stack 616 is bonded to transparent layer 620. In one embodiment, integrated lens stack 616 includes a series of lenses 618, including collimating lenses, focusing lenses, mirrored layers, spacers, or other layers which assist in controlling the type of light that illuminates the backside of substrate 614. Integrated lens stack 616 also provides additional mechanical support for image sensor 600.

Backside illumination 602 is an exemplary ray of light that is incident on image sensor 600. As backside illumination 602 passes through the different lenses 618, the light is focused and directed towards the photosensitive region of image sensor 600.

The backside thinning equates to approximately a 2-3× increase in QE*FF (with an attendant reduction in optical crosstalk) while integrated lens stack 616 provides an elegant manufacturing technique. Despite the value of these improvements, image sensors 600 that use the combination of these techniques without also including transparent layer 620 may be difficult to manufacture. In one embodiment, the use of transparent layer 620 overcomes the difficulties in handling and packaging by providing both a means for handling and mechanical support for image sensor 600. Because transparent layer 620 provides the necessary mechanical support, no handling wafer needs to be mounted to the front side of image sensor 600. Consequently, backend stack 612 is not obscured, facilitating the wafer-level testing of the image circuits via electrical connections 608. Along with the testability, the bonding of integrated lens stack 616 directly to transparent layer 620 prevents an air gap between the optics and the receiver, improving the optical quality. Moreover, the image sensing circuits on image sensor 600 are standard CMOS image sensing circuits, requiring no special fabrication techniques. Hence, a diced image sensor 600 can be a ready-made digital camera sensor of a very thin form-factor.

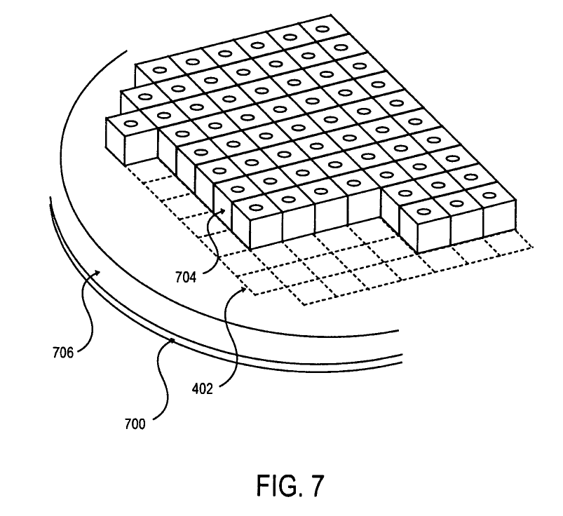

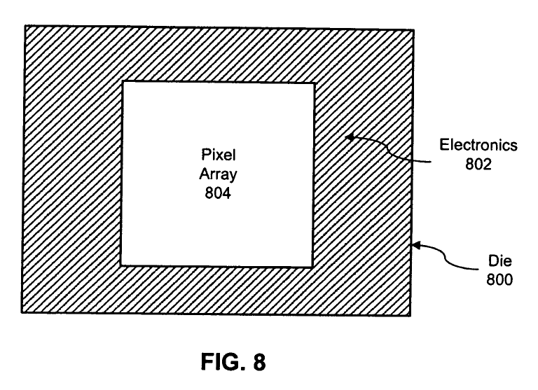

FIG. 7 illustrates one embodiment of an image sensor wafer, optical handle wafer and integrated lens stack wafer. Image sensor wafer 700 is a semiconductor wafer that has an array of image sensor dice 702 fabricated on the front side surface (the downward-facing surface of image sensor wafer 700 in FIG. 7). The backside surface (the upward-facing surface in FIG. 7) of image sensor wafer 700 has been thinned by removing material from the backside surface of image sensor wafer 700. Enough material has been removed from the backside surface to facilitate the detection of light that illuminates the backside surface of image sensor wafer 700.

In one embodiment, the backside surface is thinned until the substrate of image sensor wafer is approximately 1-10 micrometers thick, facilitating the detection of visible light. In an alternative embodiment, the backside of image sensor wafer 700 is the proper depth to facilitate the detection of selected wavelengths of electromagnetic radiation, such as infrared light.

With enough material removed from the backside surface to enable the detection of light through the backside surface, image sensor wafer 700 is thin and very fragile. Consequently, image sensor wafer 700 could easily be damaged during handling and packaging. In order to prevent this, transparent layer 706 is bonded to image sensor wafer 700. Transparent layer 706 provides a handling means and mechanical support for image sensor wafer 700.

Integrated lens stack 704 is bonded to transparent layer 706. Integrated lens stack 704 focuses light through transparent layer 706 and onto the photosensitive area of the backside of one or more image sensor dice 702. In addition, integrated lens stack 704 provides additional mechanical support for image sensor wafer 700.

FIG. 8 illustrates one embodiment of backside thinned image sensor with an integrated lens stack. Die 800 includes pixel array 804 and electronics 802. In one embodiment of die 800, pixel array 804 is located, as much as possible, approximately in the center of die 800, with electronics 802 surrounding pixel array 804. Alternatively, pixel array 804 is located off-center on die 800, with electronics 802 distributed on the remainder of die 800.

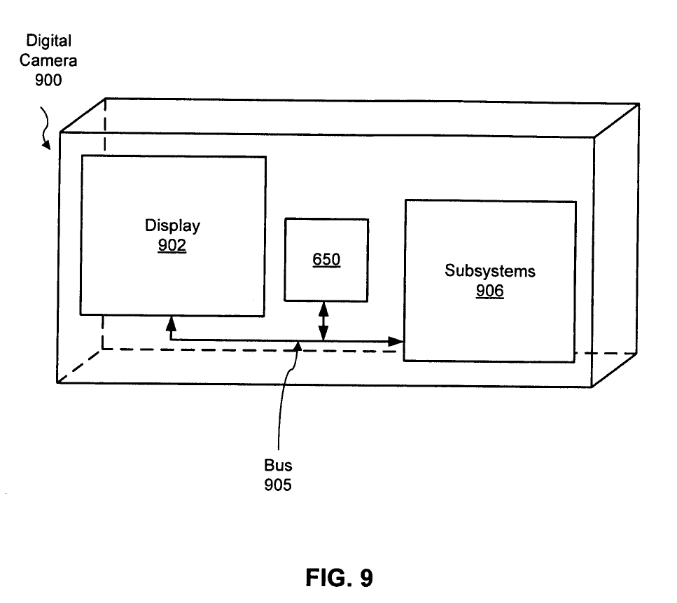

It should be noted that the backside thinned image sensor with an integrated lens stack discussed herein may be used in various applications. In one embodiment, backside thinned image sensor with an integrated lens stack may be used in a digital camera system, for example, for general-purpose photography (e.g., camera phone, still camera, video camera) or special-purpose photography, as illustrated in FIG. 9. Digital camera 900 includes a display 902, device 650, and subsystems 906 that are coupled together via bus 905. The subsystems 906 may include, for example, hardware, firmware and/or software for storage, control, and interface operations of the camera system 900 that are known to one of ordinary skill in the art; accordingly, a detailed description is not provided. Alternatively, image sensor 600 can be used in other types of applications, for example, machine vision, document scanning, microscopy, security, biometrics, etc.

While specific embodiments of the invention have been shown, the invention is not to be limited to these embodiments. The invention is to be understood as not limited by the specific embodiments described herein, but only the scope of the appended claims.

What is claimed is:

1. An apparatus, comprising:
an image sensor with image sensing circuits on a front side of the image sensor, wherein the image sensor has a thinned backside surface;
a transparent component disposed on the thinned backside surface of the image sensor; and
an integrated lens stack disposed on the transparent component.

2. The apparatus of claim 1, wherein the transparent component is an optical handle component.

3. The apparatus of claim 1, wherein the transparent component is a transparent wafer or a transparent plate.

4. The apparatus of claim 1, further comprising a color filter disposed between the image sensor and the transparent component.

5. The apparatus of claim 4, further comprising an anti-reflective layer disposed between at least one of the image sensor and the transparent component or the transparent component and the integrated lens stack.

6. The apparatus of claim 5, further comprising a p-type implant disposed in the surface of the backside of the image sensor between the image sensor and the transparent component.

7. The apparatus of claim 1, wherein the image sensor is fabricated using silicon-on-insulator-based techniques.

8. The apparatus of claim 7, wherein the image sensor is configured as a complementary metal oxide semiconductor (CMOS) device.

9. The apparatus of claim 8, wherein the apparatus has electrical connections that are in a flip-chip configuration.

10. The apparatus of claim 1, wherein the integrated lens stack contains a plurality of lens layers.

11. The apparatus of claim 10, wherein the integrated lens stack focuses at least one wavelength of light on the image sensor.

12. A method, comprising:
thinning a backside surface of a wafer, the wafer having a plurality of image sensing circuits on a front side;
disposing a transparent layer on the thinned backside surface of the wafer; and
disposing a wafer-scale integrated lens stack on the transparent layer.

13. The method of claim 12, further comprising using the transparent layer as an optical handling layer during fabrication.

14. The method of claim 12, further comprising coupling a color filter array to the backside of the wafer between the wafer and the transparent layer.

15. The method of claim 14, further comprising disposing an anti-reflective layer on at least one of the wafer, the transparent layer or the wafer scale integrated lens stack.

16. The method of claim 15, further comprising implanting a p-type implant on the backside surface of the wafer between the wafer and the transparent layer.

17. The method of claim 12, further comprising disposing a handling wafer on the front side of the wafer, wherein the handling wafer is used to handle the wafer during fabrication.

18. The method of claim 17, further comprising removing the handling wafer from the front side surface of the wafer after handling the wafer during fabrication.

19. The method of claim 12, further comprising wafer testing the image sensing circuits.

20. The method of claim 12, further comprising disposing bump bonds on the front side of the wafer.

21. The method of claim 12, further comprising dicing the wafer.

22. The method of claim 12, further comprising fabricating the wafer using a silicon-on-insulator-based techniques.

23. A method, comprising:
providing an image sensor with a thinned backside surface, wherein a transparent component is disposed on the thinned backside surface and an integrated lens stack is disposed on the transparent component;
focusing incident light through the integrated lens stack on to the backside of the image sensor; and
processing an electrical signal generated by the backside illuminated image sensor.

24. The method of claim 23, wherein processing the electrical signal further comprises at least one of converting the electrical signal from an analog signal to a digital signal or adjusting the electrical signal.

25. The method of claim 23, wherein focusing incident light further comprises focusing a particular wavelength of the incident light on the backside of the image sensor.

26. An apparatus, comprising:
a semiconductor wafer, wherein the semiconductor wafer has a plurality of image sensing circuits on the front side and a thinned backside surface;
a transparent layer disposed on the thinned backside surface of the semiconductor wafer; and
a wafer-scale integrated lens stack coupled to the transparent layer.

27. The apparatus of claim 26, wherein the transparent layer is an optical handling wafer.

28. The apparatus of claim 26, further comprising a color filter array disposed between the semiconductor wafer and the transparent layer.

29. The apparatus of claim 28, further comprising an anti-reflective layer disposed between the semiconductor wafer and the transparent layer.

30. The apparatus of claim 29, further comprising p-type implant disposed in the backside surface of the semiconductor wafer between the semiconductor wafer and the transparent layer.

31. The apparatus of claim 26, wherein the wafer-scale integrated lens stack contains a plurality of lens layers.

32. The apparatus of claim 26, wherein the semiconductor wafer is configured as a silicon-on-insulator type wafer.
